(19) United States
(12) Patent Application Publication
(10) Pub. No.: US 2013/0037094 A1
(43) Pub. Date: Feb. 14, 2013

(54) CONDUCTIVE PASTES AND SOLAR CELLS COMPRISING THE SAME

(71) Applicants: Yu-Ming WANG, Taichung City (TW); Kao-Der Chang, Taichung City (TW); Chian-Fu Huang, Keelung City (TW); Chien-Liang Wu, Pingtung County (TW); Jun-Chin Liu, Hsinchu City (TW)

(72) Inventors: Yu-Ming WANG, Taichung City (TW); Kao-Der Chang, Taichung City (TW); Chian-Fu Huang, Keelung City (TW); Chien-Liang Wu, Pingtung County (TW); Jun-Chin Liu, Hsinchu City (TW)

(21) Appl. No.: 13/407,557

(22) Filed: Feb. 28, 2012

(30) Foreign Application Priority Data
Aug. 8, 2011 (TW) 100128143

(51) Int. Cl. H01L 31/0224; H01B 1/22; H01L 31/0232; H01B 1/20

(52) U.S. Cl. 136/256; 252/500; 252/514; 252/512

(57) ABSTRACT

A conductive paste is provided. The conductive paste includes a polymer matrix and a filler blended in the polymer matrix, wherein the filler is non-spherical and at least one dimension of the filler has a length greater than or equal to λ/2n, wherein λ is a wavelength of light reflected by the conductive paste and n is a refractive index of the filler, and the polymer matrix and the filler have a weight ratio of 3:7 to 7:3.

### CROSS REFERENCE TO RELATED APPLICATIONS

This Application claims priority of Taiwan Patent Application No. 100128143, filed on Aug. 8, 2011, the entirety of which is incorporated by reference herein.

### BACKGROUND

1. Field

The disclosure relates to a conductive paste, and more particularly to a conductive paste with high reflectivity and a solar cell comprising the same.

2. Description of the Related Art

Due to the advantages of rapid production, low pollution and low equipment cost which the printing process has, in recent years, the amount of usage of printable conductive paste has tended to greatly increase which can be widely applied in producing touch components, electronic circuits, functional elements and membrane keypads etc. The design of metal conductive pastes will differ based on the application field and area differences. For instance, the conductive paste which can be applied to flexible electronic material needs to have the characteristics of flexibility and high adhesion with a flexible substrate etc. Therefore, all kinds of functional conductive pastes are continually being developed. With the growing awareness of environmental protection recently, more and more attention has been gradually paid to alternative energy products and energy-saving products. For example solar cells and light emitting diodes (LEDs). Therefore, the development of corresponding conductive pastes is in no time.

The main function of solar cells is to convert light energy into electrical energy. When sunlight illuminates a solar cell, its light energy can raise the potential energy of the outer electrons of semiconductor atoms making electron-hole pairs separate while the separated electrons and holes form current (electrical energy). A layer of metal (silver or aluminum) as an electrode is sputtered (or printed) on a bottom of a traditional solar cell which causes the produced electrons to convey to the outside thereof. Although a better conductivity effect, in order to lengthen a light path inside of the solar cell to increase the probability of light absorption, a substrate with a microstructure (TCO glass) is mostly adopted. Accordingly, the silver sputtered on the substrate also has the similar microstructure as the substrate, which causes a surface plasmon effect and unnecessary light absorption, resulting in indifferent reflectivity. Also, light adsorbed by the surface plasmon effect cannot convert into electrical energy usage, since it will be transmitted to the cell in the way of heat which decreases efficiency. Therefore sunlight cannot be used efficiently. In order to increase efficiency of solar cells, the Oerlikon Company provides a layer of white paint which is coated on a bottom of a solar substrate. After light enters the interior of the solar cell to excite and separate electron-hole pairs, the light is reflected to perform a second excitation. Although this technology may resolve the optical loss caused by an interface, however, the thickness of the transparent conductive layer needs to be increased (>1.5 μm) in order to have enough conductivity and the problem of adsorption of long-wavelength lights is caused by the carriers of the transparent conductive layer. In conclusion, reuse of reflected incident light plays an important role in the improvement of the efficiency of solar cells.

### BRIEF SUMMARY

One embodiment provides a conductive paste, comprising: a polymer matrix; and a filler blended in the polymer matrix, wherein the filler is non-spherical and at least one dimension of the filler has a length greater than or equal to λ/2n, wherein λ is a wavelength of light reflected by the conductive paste and n is a refractive index of the filler, and the polymer matrix and the filler have a weight ratio of 3:7 to 7:3.

The filler comprises gold, silver, copper, aluminum, titanium or a mixture thereof. The filler comprises tube, wire, rod, sheet, ribbon or a combination thereof. The wavelength of the light reflected by the conductive paste ranges from 200 nm to 1,200 nm.

One embodiment provides a solar cell, comprising: a substrate; a first conductive layer formed on the substrate; a photoelectric conversion layer formed on the first conductive layer; a second conductive layer formed on the photoelectric conversion layer; and a conductive reflection layer formed on the second conductive layer, wherein the conductive reflection layer comprises the disclosed conductive paste.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawing, wherein:

FIG. 1 shows a solar cell structure according to one embodiment of the disclosure;

FIG. 2 shows a relationship between the wavelength (within 200-1,200 nm) of reflected light and an feature length (λ/2n) of one dimension of a filler according to one embodiment of the disclosure;

FIG. 3 shows reflectivity of various pastes on a flat substrate (with a surface roughness less than 5 nm) according to one embodiment of the disclosure;

FIG. 4 shows reflectivity of various pastes on a textured substrate (with a surface roughness of about 100 nm) according to one embodiment of the disclosure; and

FIG. 5 shows a comparison of photoelectric conversion efficiency of thin-film solar cell according to one embodiment of the disclosure.

### DETAILED DESCRIPTION

One embodiment provides a conductive paste comprising a polymer matrix and a filler blended in the polymer matrix. Specifically, the filler blended in the polymer matrix is non-spherical and at least one dimension of the filler has a length greater than or equal to λ/2n, wherein λ is a wavelength of light reflected by the conductive paste, ranging from 200 nm to 1,200 nm, and n is a refractive index of the filler. In the conductive paste, the polymer matrix and the filler have a weight ratio of 3:7 to 7:3, preferably 7:3 to 6:4.

The polymer matrix may comprise acrylic resin, ethylene vinyl acetate resin, polycarbonate (PC), polystyrene (PS), epoxy resin, urethane resin, polyvinyl alcohol, polyvinyl pyrrolidone, cellulose or the like. The cellulose may comprise methyl cellulose, ethyl cellulose or hydroxyethyl cellulose.

The filler may comprise gold, silver, copper, aluminum, titanium or a mixture thereof. The shape of the filler may comprise tube, wire, rod, sheet, ribbon or a combination thereof. In an embodiment, silver sheet and silver wire have a weight ratio of, for example 1:1 to 7:1, preferably 3:1.

The present conductive paste further comprises an auxiliary blended in the polymer matrix. The auxiliary may be a defoamer or a rheology control agent.

The defoamer may be alcohols, polyethers, amides, fatty acid esters, organosilicon polymers, ketones, aromatic compounds or a mixture thereof. The alcohols may be alkyl alcohols (for example octanol or isopentanol). The polyethers may be ethylene glycol monobutyl ether. The ketones may be diisobutyl ketone. In an embodiment, the auxiliary containing ethylene glycol monobutyl ether may be BYK020 (a mixture of ethylene glycol monobutyl ether, ethyl alcohol and gasoline) or BYKETOL WS (8% of ethylene glycol monobutyl ether). The auxiliary containing diisobutyl ketone may be BYK066N or BYK060N. The auxiliary containing aromatic compounds with high boiling point may be BYK055 (aromatic compounds with high boiling point/propylene glycol methyl ether acetate) or BYK057 (aromatic compounds with high boiling point/propylene glycol methyl ether acetate).

The rheology control agent may be N-methyl pyrrolidone (NMP), polypropylene glycol or a mixture thereof. The rheology control agent containing N-methyl pyrrolidone (NMP) may be BYK410 or BYK420. The rheology control agent containing polypropylene glycol may be BYK425.

The present conductive paste further comprises at least one solvent, for example ketones, alcohols, ethers, esters, water, other proper organic solvents or a mixture thereof. In an embodiment, the ketones may comprise acetone, cyclohexanone, isophorone or N-methyl pyrrolidone (NMP). The alcohols may comprise ethanol, terpineol, ethylene glycol or isopropanol. The ethers may comprise ethylene glycol monomethyl ether, propylene glycol dimethyl ether or ethylene glycol monobutyl ether. The esters may comprise ethyl acetate, butyl lactate, propylene glycol monoether acetate, carbonic acid dimethyl ester or butyrolactone. Other proper organic solvents may be dimethyl sulfoxide. In an embodiment, the solvent may be a mixture of N-methyl pyrrolidone (NMP) and one of ketones, alcohols, ethers, esters or water. In an embodiment, the solvent may be a mixture of butyrolactone and one of ketones, alcohols, ethers, esters or water. In an embodiment, the solvent may be a mixture of terpineol and another alcohol. In an embodiment, the solvent added in the conductive paste mainly adopts one or more low-volatile liquids and compatible low-boiling-point solvents to reduce paste-forming temperature and evaporation rate. The solvent has a boiling point or azeotropic point of about 90-150° C., preferably 90-110° C.

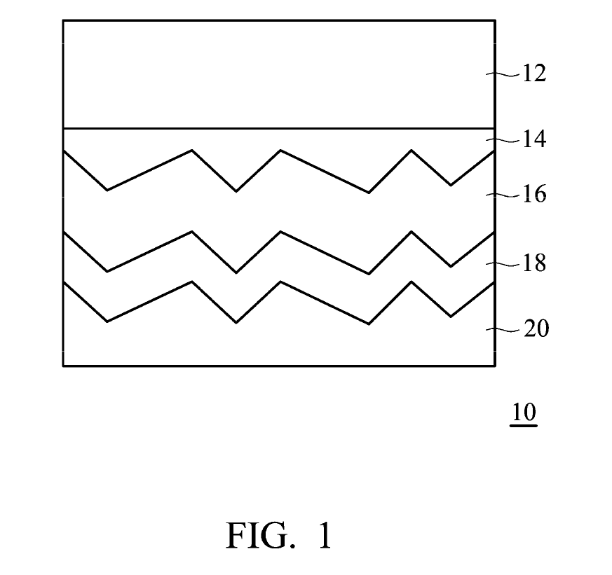

Referring to FIG. 1, in accordance with one embodiment, a solar cell is provided. The solar cell 10 comprises a substrate 12, a first conductive layer 14, a photoelectric conversion layer 16, a second conductive layer 18 and a conductive reflection layer 20. The first conductive layer 14 is formed on the substrate 12. The photoelectric conversion layer 16 is formed on the first conductive layer 14. The second conductive layer 18 is formed on the photoelectric conversion layer 16. The conductive reflection layer 20 is formed on the second conductive layer 18. Specifically, the conductive reflection layer 20 comprises the disclosed conductive paste.

The substrate 12 may be a glass substrate.

The first conductive layer 14 and the second conductive layer 18 may comprise indium tin oxide (ITO), fluorine-doped tin oxide (FTO), zinc oxide (ZnO), gallium-doped zinc oxide (GZO), indium-gallium-zinc oxide (IGZO), aluminum doped zinc oxide (AZO) or the like.

The photoelectric conversion layer 16 may comprise crystalline silicon, amorphous silicon, gallium arsenide (GaAs), cadmium telluride (CdTe) or copper indium gallium selenide (CIGS).

The second conductive layer 18 has a thickness of about 50-100 nm.

The present conductive paste may be applied to printed circuit boards (PCBs) of light emitting diodes (LEDs).

The disclosure mainly adopts non-diffractive material or a mixture of such material as a conductive filler to prepare a printable conductive paste with high reflectivity. The conductive paste can be shaped on a bottom of a solar cell through heating (of about 50-150° C.) or under a natural temperature. The solar cell utilizing the present conductive paste reduces light absorption and light scattering caused by an interface, fabrication cost and thickness of a transparent conductive layer.

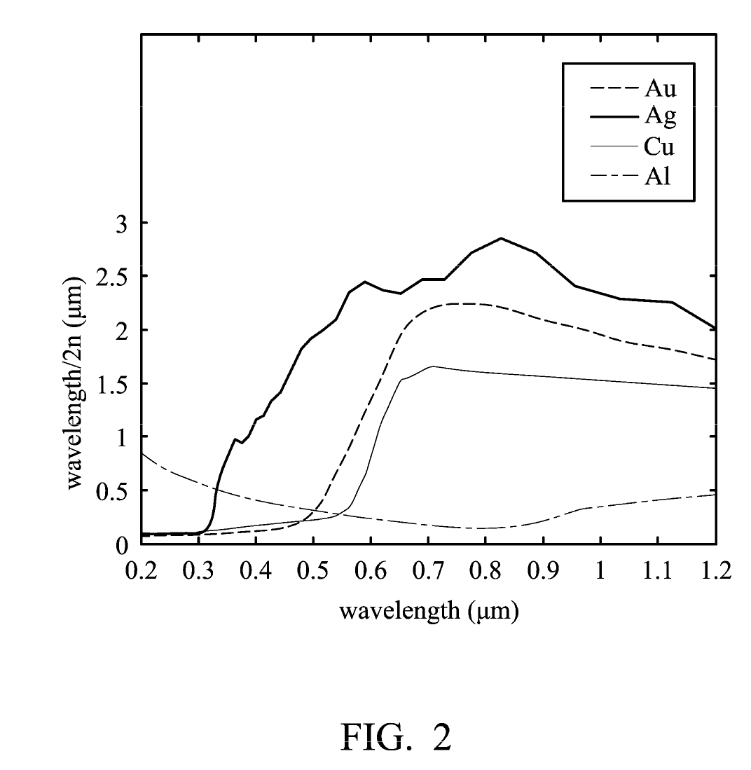

At least one dimension of the present non-diffractive material satisfies d≧λ/(2n), wherein d is an feature length of one dimension of a filler, λ is a wavelength of reflected light and n is a refractive index of the non-diffractive material. The shape of the non-diffractive material utilized in the disclosure may comprise tube, wire, rod or sheet, preferably wire and sheet. The material of the filler may be, for example gold, silver, copper or aluminum. The wavelength of the reflected light ranges from 200 nm to 1,200 nm. The feature length d of one dimension of the filler satisfies d≧λ/(2n). Referring to FIG. 2, when the material of the filler is gold, d≧2.3 μm. When the material of the filler is silver, d≧2.8 μm. When the material of the filler is copper, d≧1.7 μm. When the material of the filler is aluminum, d≧0.8 μm.

Additionally, the present metal conductive paste with high reflectivity can also be applied to line production of an LED panel. A patterned line can be produced on a PCB of a conventional LED through the conductive paste. The present conductive paste with high reflectivity reflects most light generated from the LED to the environment, reducing optical loss caused by scattering or absorption from material.

Preparations and Electrical Properties of Various Pastes

### EXAMPLE 1

The Present Paste I with Fillers of Nano Silver Sheet and Nano Silver Wire:

120 g of acrylic resin (Company: DSM, Type: NEO B890) was dissolved in 35 g of NMP and 15 g of acetone with stirring using an agitator under air for 30 minutes until cooling to room temperature to form a paste. Next, 30 g of nano silver sheet (with a length of 5 μm, a width of 5 μm and a thickness of about 70 nm), 10 g of nano silver wire (with a diameter of about 80-100 nm and a length of 10-25 μm), 0.5 g of a foam stabilizer (Company: BYK, Type: BYK390) and 0.5 g of a defoamer (Company: BYK, Type: BYKWS) were added to the paste with continuous stirring at a speed of 200 rpm for 30 minutes. The paste was then rolled for three times by a three-roller printing ink miller to disperse the paste. The paste was then coated on a glass substrate. After heating at 100° C. for 10 minutes, the paste was shaped. The shaped conductive layer was measured using a four-point probe. The sheet resistance thereof was 0.0054 ohm/sq.

### EXAMPLE 2

The Present Paste II with Fillers of Nano Silver Sheet and Nano Silver Wire:

17 g of ethyl cellulose was dissolved in 45 g of terpineol with stirring using an agitator under air for 30 minutes until cooling to room temperature to form a paste. Next, 20 g of nano silver sheet (with a length of 5 μm, a width of 5 μm and a thickness of about 70 nm), 20 g of nano silver wire (with a diameter of about 80-100 nm and a length of 10-25 μm) and 0.4 g of a defoamer (Company: BYK, Type: BYKetol-OK) were added to the paste with continuous stirring at a speed of 200 rpm for 30 minutes. The paste was then rolled for three times by a three-roller printing ink miller machine to disperse the paste. The paste was then coated on a glass substrate. After heating at 100° C. for 10 minutes, the paste was shaped. The shaped conductive layer was measured using a four-point probe. The sheet resistance thereof was 0.0042 ohm/sq.

### EXAMPLE 3

The Present Paste III with Fillers Of Nano Silver Sheet And Nano Silver Wire:

20 g of acrylic resin (Company: DSM, Type: NEO B890) was dissolved in 35 g of NMP and 15 g of acetone with stirring using an agitator under air for 30 minutes until cooling to room temperature to form a paste. Next, 35 g of nano silver sheet (with a length of 5 μm, a width of 5 μm and a thickness of about 70 nm), 5 g of nano silver wire (with a diameter of about 80-100 nm and a length of 10-25 μm), 0.5 g of a foam stabilizer (Company: BYK, Type: BYK390) and 0.5 g of a defoamer (Company: BYK, Type: BYKWS) were added to the paste with continuous stirring at a speed of 200 rpm for 30 minutes. The paste was then rolled for three times by a three-roller printing ink miller to disperse the paste. The paste was then coated on a glass substrate. After heating at 100° C. for 10 minutes, the paste was shaped. The shaped conductive layer was measured using a four-point probe. The sheet resistance thereof was 0.0417 ohm/sq.

One embodiment of the disclosure adopts non-diffractive nano conductive material as a filler to reduce light scattering and light absorption from material to prepare a printable conductive paste with high reflectivity and improve conductive property. The disclosure utilizes nano silver sheet with high reflectivity and nano silver wire capable of increasing contact probability to reduce contact resistance as fillers to prepare a conductive paste with high conductivity and high reflectivity.

### COMPARATIVE EXAMPLE 1

A Conventional Paste with a Filler of Titanium Dioxide Particles:

20 g of acrylic resin (Company: DSM, Type: NEO B890) was dissolved in 45 g of NMP with stirring under air until cooling to room temperature to form a paste. Next, 30 g of titanium dioxide particles (diameter: 100 nm) was added to the paste with continuous stirring at a speed of 200 rpm for 30 minutes. The paste was then rolled for three times by a three-roller machine to disperse the paste. Next, the paste was respectively coated on a flat glass and a textured glass to detect the reflectivity and electrical property thereof. The result obtained from four-point probe measurement shows that the reflection layer utilizing the titanium dioxide particles as a filler without conductivity.

### COMPARATIVE EXAMPLE 2

A Conventional Paste with a Filler of Nano Silver Particles:

In addition to reflectivity of a back electrode, conductivity thereof is also one of the factors affecting conversion efficiency of a solar cell. In this example, 20 nm nano silver particles were utilized as a filler to prepare a reflectable paste with conductivity. First, 20 g of acrylic resin (Company: DSM, Type: NEO B890) was dissolved in 40 g of NMP and 15 g of acetone to form a paste. The azeotropic point and evaporation rate of the solvent were thus reduced. The paste was stirred using an agitator under air for 30 minutes until cooling to room temperature. Next, 35 g of nano silver particles (with a diameter of 20 nm) and 0.5 g of octanol were added to the paste with continuous stirring at a speed of 200 rpm for 30 minutes. The paste was then rolled for three times by a three-roller printing ink miller to disperse the paste. The paste was then coated on a glass substrate. After heating at 100° C. for 10 minutes, the paste was shaped. The shaped conductive layer was measured using a four-point probe. The sheet resistance thereof was 0.25 ohm/sq.

### COMPARATIVE EXAMPLE 3

A Conventional Sputtered Silver as a Back Electrode:

Presently, sputtered silver is commonly utilized as a back electrode of a thin-film solar cell, with a thickness of about 200 nm and a sheet resistance of about 0.0036 ohm/sq.

The compositions and electrical properties of the above-mentioned pastes are shown in Table 1.

TABLE 1

| | Com. | Com. | Com. | | | |
|---|---|---|---|---|---|---|
| | Example 1 | Example 2 | Example 3 | Example 1 | Example 2 | Example 3 |
| Filler | Titanium | Nano silver | — | Nano silver | Nano silver | Nano silver |
| | dioxide | particles | | wire (10 g) | wire (20 g) | wire (5 g) |
| | particles | (35 g) | | Nano silver | Nano silver | Nano silver |
| | (30 g) | | | sheet (30 g) | sheet (20 g) | sheet (35 g) |
| Solvent | NMP | NMP | — | NMP | Terpineol | NMP |
| | (45 g) | (40 g) | | (35 g) | (45 g) | (35 g) |
| | | Acetone | | Acetone | | Acetone |
| | | (15 g) | | (15 g) | | (15 g) |
| Polymer | Acrylic | Acrylic | — | Acrylic | Ethyl | Acrylic |
| matrix | resin (NEO | resin (NEO | | resin (NEO | cellulose | resin (NEO |
| | B890)(20 g) | B890)(20 g) | | B890)(20 g) | (17 g) | B890)(20 g) |
| Auxiliary | BYK020 | Octanol | — | BYK390 | BYKetol- | BYK390 |
| | (0.5 g) | (0.5 g) | | (0.5 g) | OK | (0.5 g) |
| | | | | BYKWS | (0.4 g) | BYKWS |
| | | | | (0.5 g) | | (0.5 g) |
| Sheet | NA | 0.25 | 0.0036 | 0.0054 | 0.0042 | 0.0417 |
| resistance | | | | | | |
| (ohm/sq) | | | | | | |

In accordance with Table 1, when the ratio of the nano silver wire in the conductive paste with high reflectivity is increased, the conductivity of the conductive paste is also increased. The reason may be that the nano wire connects to surrounding conductive material, thereby effectively reducing the contact resistance of the conductive paste.

### EXAMPLE 4

Reflectivity of Various Pastes on a Flat Substrate

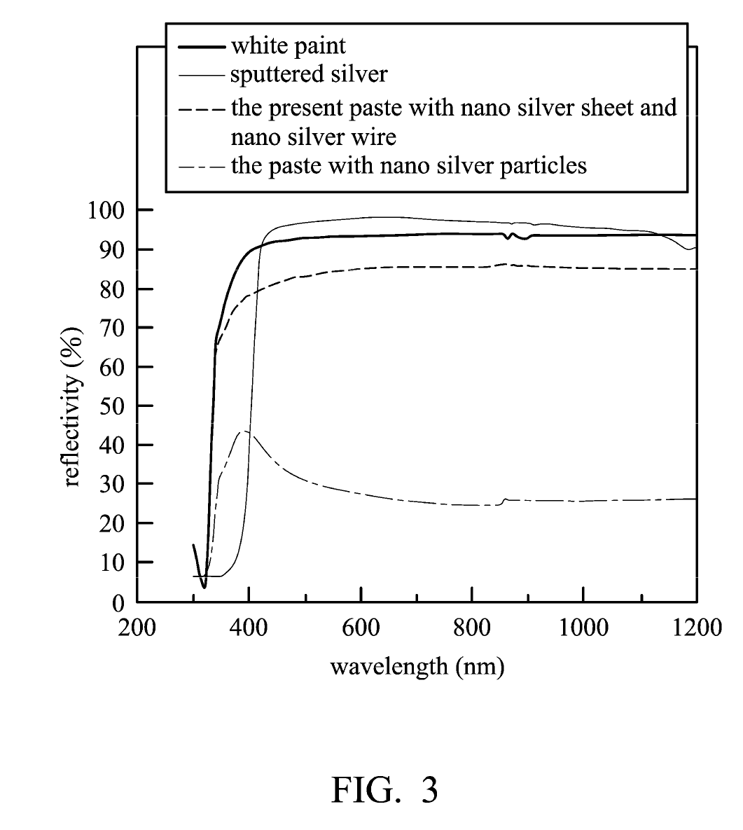

To comprehend reflectivity of various pastes on a flat substrate, in this example, the pastes prepared by Comparative Examples 1 and 2 and Example 1 were respectively coated on a glass substrate. The reflectivity thereof was compared with that of sputtered silver commonly utilized on a back electrode of a solar cell (Comparative Example 3) by spectrum analysis, as shown in FIG. 3. The results show indicate that, after heating at 100° C. for 10 minutes, the average reflectivity of the paste (white paint) prepared by Comparative Example 1 on the glass substrate (with a surface roughness <5 nm) achieved 95.5% (within a wavelength of 400-1,200 nm), but the paste had no conductivity.

Additionally, after the paste prepared by Comparative Example 2 was heated to be shaped on the glass substrate, although the sheet resistance of the paste was 0.25 ohm/sq, the reflectivity thereof within the wavelength of 400-1,200 nm was merely 27.5%. The reason may be that the nano silver particles have larger light scattering ability and surface plasmon light absorption, due to surface plasma effect resulting in substantially decreased reflectivity. In Comparative Example 3, the average reflectivity of the silver which was directly sputtered on the glass substrate having a surface roughness less than 5 nm achieved 93.5%, next to that of the white paint prepared by Comparative Example 1.

In Example 1, a mixture of nano silver sheet and nano silver wire (3:1) was utilized as fillers (66.7 wt %) of the conductive paste. The paste was reflectable and conductive due to combination with the high-reflectivity silver sheet and high-conductivity silver wire. The result indicates that the average reflectivity of the paste containing the nano silver sheet/nano silver wire mixture within the wavelength of 400-1,200 nm was 84.7%. Thus, the reflectivity and conductivity of the present paste were higher than those of the paste containing nano silver particles by above three times, as shown in Table 2.

TABLE 2
Reflectivity of various pastes on a flat substrate (glass)

| | Com. | Com. | Exam- | Com. |
|---|---|---|---|---|
| Paste | Example 1 | Example 3 | ple 1 | Example 2 |
| Reflectivity (%) | 95.5 | 93.5 | 84.7 | 27.5 |
| (400-1,200 nm) | | | | |

### EXAMPLE 5

Reflectivity of Various Pastes on a Textured Substrate

In a solar cell, a textured substrate (with a surface roughness of about 100 nm) was utilized to lengthen a light path within the cell to improve cell efficiency. Sunlight is reflected by a back electrode to excite a photoelectric conversion layer to improve conversion efficiency. In this example, the pastes of Comparative Examples 1-3 and Example 1 were coated on a textured substrate. After coating, the color of the textured substrate coated with the paste of Comparative Example 3 was khaki. The color of the textured substrate coated with the paste of Comparative Example 2 was dark gray. The color of the textured substrate coated with the paste containing nano silver sheet/nano silver wire of Example 1 was white. The results illustrate that the present conductive paste prepared by the nano silver sheet/nano silver wire on the textured substrate had a higher reflectivity. The reason is that the silver sputtered on the substrate grew with the surface profile which is considered nano silver particles located on the surface of the cell, resulting in strong back scattering and surface plasmon resonance. A part of the bands of light were absorbed so that the scattered light is khaki. The size of the present fillers of nano silver sheet and nano silver wire causes redshift resonance.

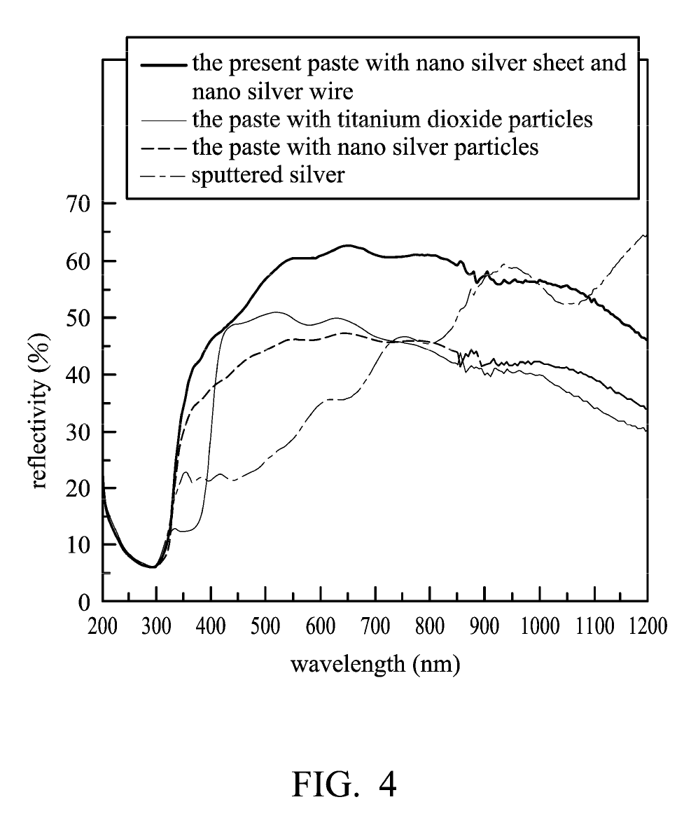

The reflectivity of the pastes of Comparative Examples 1-3 and Example 1 on the textured substrate was detected using a spectrometer and shown in FIG. 4. The results show that the average reflectivity of the textured substrate coated with the conductive paste of Example 1 achieved 56.8%. The average reflectivity of the textured substrate sputtered with a 500 nm-thickness thin film (Comparative Example 3) within the wavelength of visible light was 44.6%. The average reflectivity of the textured substrates respectively coated with the pastes of Comparative Example 1 and Comparative Example 2 within the wavelength of 400-1,200 nm was 42.9% and 42.1%, respectively, as shown in Table 3. The results prove that the present conductive paste utilized as a back electrode of a solar cell can improve its reflectivity.

TABLE 3
Reflectivity of various pastes on a textured substrate (glass)

| | Com. | Com. | Exam- | Com. |
|---|---|---|---|---|
| Paste | Example 1 | Example 3 | ple 1 | Example 2 |
| Reflectivity (%) | 42.9 | 44.6 | 56.8 | 42.1 |
| (400-1,200 nm) | | | | |

### EXAMPLE 6

Comparison of Photoelectric Conversion Efficiency of Thin-Film Solar Cell

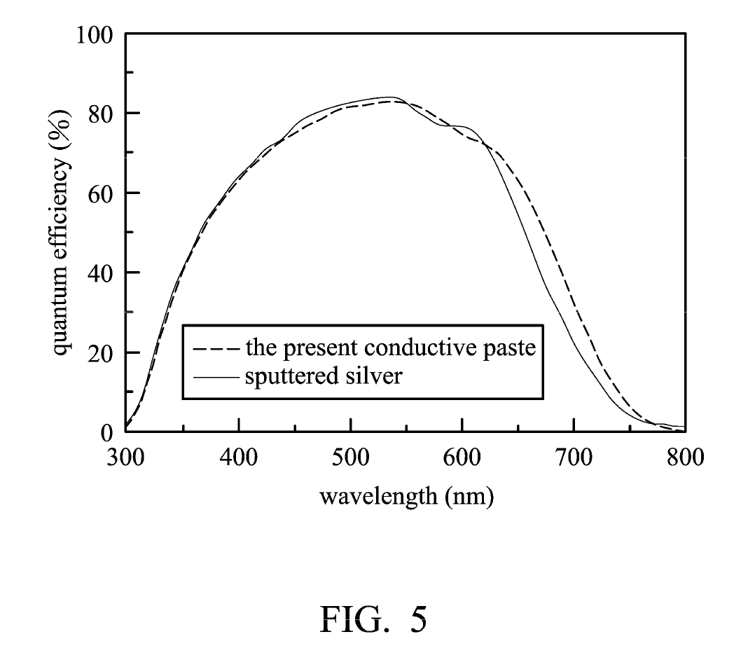

In this example, the conductive paste of Example 1 was coated and the silver was sputtered (Comparative Example 3), respectively, on the back of the same amorphous thin-film solar cell. The conversion efficiency and electrical properties of the solar cell were detected and shown in FIG. 5. In accordance with the figure of quantum efficiency and wavelength, at the wavelength of 550 nm above, the efficiency of the solar cell utilizing the present conductive paste was higher than that of the conventional solar cell sputtered with silver for about 5% or above, or up to 12% or above. The reason may be that the reflectivity of the present conductive paste is higher than that of the sputtered silver at the wavelength of 550 nm above. Additionally, the silver was sputtered on the entire surface of the solar cell. However, the present conductive paste was coated on the partial surface of the solar cell, leaving a proper area for overflow of the conductive paste during the screen printing process.

The electrical properties and photoelectric conversion efficiency of the amorphous solar cell simultaneously with the conductive paste of Example 1 and the sputtered silver of Comparative Example 3 were detected and shown in Table 4. In accordance with the detection results, the solar cell with sputtered silver had Voc=0.84V, Jsc=0.013 and efficiency=8.28%. The solar cell with the present conductive paste had Voc=0.85V, Jsc=0.015 and efficiency=9.02%. The results indicate that, although the coverage area of the present conductive paste is smaller, the photoelectric conversion efficiency of the solar cell utilizing the present conductive paste is still higher than that of the solar cell sputtered with silver because of the present conductive paste with improved reflectivity. Compared with the conversion efficiency between the sputtered silver and the present conductive paste with high reflectivity, the present conductive paste improves efficiency by 0.742%. In addition to reducing material cost of a solar cell by 10.4%, equipment cost can further be reduced. In the fabrication process, a laser bombardment procedure can be omitted to increase a production capacity thereof.

TABLE 4
the performance of the solar cell with the present conductive paste
containing nano silver sheet/nano silver wire and the sputtered silver

| | Com. | |
|---|---|---|
| | Example 3 | Example 1 |
| Voc (V) | 0.84 | 0.85 |
| Jsc (A/cm²) | 0.013 | 0.015 |
| Photoelectric conversion | 8.28 | 9.02 |
| efficiency (%) | | |

### EXAMPLE 7

Comparison of Photoelectric Conversion Efficiency of Thin-Film Solar Cell Modules

The conductive paste of Example 1 was utilized and the silver was sputtered (Comparative Example 3), respectively, to prepare back electrodes of thin-film solar cell modules and the performance of the solar cells was detected. The coverage area of the thin-film solar cell module prepared by sputtered silver was the largest. The conductive paste of Example 1 was coated on the back of the thin-film solar cell by screen printing, with a coverage area of 81%.

The performance of the two solar cells with various back electrodes was detected and the results indicate that the efficiency of the thin-film solar cell prepared by the present conductive paste with high reflectivity was the highest. Although the coverage area thereof was merely 81%, the photoelectric conversion efficiency thereof achieved about 6.6%. The reason is absorption of short-wavelength light by silver can be effectively reduced using the present conductive paste with high reflectivity. Also, the heat generated by photothermal conversion can be reduced, improving cell efficiency. The conversion efficiency of the solar cell with the back electrode prepared by sputtered silver was merely 5.99% due to the surface plasmon resonance of silver caused by the textured structure, as shown in Table 5. The back electrode which can prepare solar cells through screen printing or transfer printing processes has already been developed. In addition to omitting the laser scribing process, conversion efficiency was further improved by 0.6%, effectively reducing equipment cost and material cost.

TABLE 5
the performance of the solar cell modules with the present conductive paste
containing nano silver sheet/nano silver wire and the sputtered silver

| | | | Photoelectric |
|---|---|---|---|
| | | | conversion |
| | Voc (V) | Jsc (A/cm²) | efficiency (%) |
| No paste | 10.2 | 0.0010 | 5.86 |
| Com. Example 3 | 10.2 | 0.0009 | 5.99 |
| Example 1 | 10.2 | 0.0011 | 6.60 |
| (coverage area of | | | |
| 81%) | | | |

The disclosure mainly adopts non-diffractive material or a mixture of such material as a conductive filler to prepare a printable conductive paste with high reflectivity. The conductive paste can be shaped on a bottom of a solar cell through heating (of about 50-150° C.) or under a natural temperature. The solar cell utilizing the present conductive paste reduces light absorption and light scattering caused by an interface, fabrication cost and thickness of a transparent conductive layer.

At least one dimension of the present non-diffractive material satisfies d≧λ/(2n), wherein d is an feature length of one dimension of a filler, λ is a wavelength of reflected light and n is a refractive index of the non-diffractive material. The shape of the non-diffractive material utilized in the disclosure may comprise tube, wire, rod or sheet, preferably wire and sheet. The material of the filler may be, for example gold, silver, copper or aluminum. The wavelength of the reflected light ranges from 200 nm to 1,200 nm. The feature length d of one dimension of the filler satisfies d≧λ/(2n). Referring to FIG. 2, when the material of the filler is gold, d≧2.3 μm. When the material of the filler is silver, d≧2.8 μm. When the material of the filler is copper, d≧1.7 μm. When the material of the filler is aluminum, d≧0.8 μm.

Additionally, the present metal conductive paste with high reflectivity can also be applied to line production of an LED panel. A patterned line can be produced on a PCB of a conventional LED through the conductive paste. The present conductive paste with high reflectivity reflects most light generated from the LED to the environment, reducing optical loss caused by scattering or absorption from material.

While the disclosure has been described by way of example and in terms of preferred embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A conductive paste, comprising:
a polymer matrix; and
a filler blended in the polymer matrix, wherein the filler is non-spherical and at least one dimension of the filler has a length greater than or equal to λ/2n, wherein λ is a wavelength of light reflected by the conductive paste and n is a refractive index of the filler, and the polymer matrix and the filler have a weight ratio of 3:7 to 7:3.

2. The conductive paste as claimed in claim 1, wherein the polymer matrix comprises acrylic resin, ethylene vinyl acetate resin, epoxy resin, urethane resin, cellulose or the like.

3. The conductive paste as claimed in claim 1, wherein the filler comprises gold, silver, copper, aluminum, titanium or a mixture thereof.

4. The conductive paste as claimed in claim 1, wherein the filler comprises tube, wire, rod, sheet, ribbon or a combination thereof.

5. The conductive paste as claimed in claim 1, further comprising an auxiliary blended in the polymer matrix.

6. The conductive paste as claimed in claim 1, further comprising at least one solvent having a boiling point or azeotropic point of 90-150° C.

7. The conductive paste as claimed in claim 1, wherein the wavelength of the light reflected by the conductive paste ranges from 200 nm to 1,200 nm.

8. A solar cell, comprising:
a substrate;
a first conductive layer formed on the substrate;
a photoelectric conversion layer formed on the first conductive layer;
a second conductive layer formed on the photoelectric conversion layer; and
a conductive reflection layer formed on the second conductive layer, wherein the conductive reflection layer comprises a conductive paste as claimed in claim 1.

9. The solar cell as claimed in claim 8, wherein the first and second conductive layers comprise indium tin oxide (ITO), fluorine-doped tin oxide (FTO), zinc oxide (ZnO), gallium-doped zinc oxide (GZO), indium-gallium-zinc oxide (IGZO), aluminum doped zinc oxide (AZO) or the like.

10. The solar cell as claimed in claim 8, wherein the photoelectric conversion layer comprises crystalline silicon, amorphous silicon, gallium arsenide (GaAs), cadmium telluride (CdTe) or copper indium gallium selenide (CIGS).

11. The solar cell as claimed in claim 8, wherein the second conductive layer has a thickness of 50-100 nm.
